(19) United States
(12) Patent Application Publication
(10) Pub. No.: US 2025/0313512 A1
(43) Pub. Date: Oct. 9, 2025

(54) CERAMIC SUSCEPTOR

(71) Applicant: NGK INSULATORS, LTD., Nagoya-City (JP)

(72) Inventors: Yutaka UNNO, Handa-Shi (JP); Keita YAMANA, Nagoya-Shi (JP); Akiyoshi HATTORI, Nagoya-Shi (JP); Kazuhiro NOBORI, Handa-Shi (JP)

(73) Assignee: NGK INSULATORS, LTD., Nagoya-City (JP)

(21) Appl. No.: 19/072,011

(22) Filed: Mar. 6, 2025

(30) Foreign Application Priority Data
Apr. 3, 2024 (WO) PCT/JP2024/013744
Dec. 3, 2024 (JP) 2024-210491

(51) Int. Cl. C04B 35/581; H05B 3/28

(52) U.S. Cl. CPC C04B 35/581; H05B 3/283; C04B 2235/3865; C04B 2235/3886; C04B 2235/72; C04B 2235/763; C04B 2235/87

(57) ABSTRACT

A ceramic susceptor includes a substrate-mounting plate. The substrate-mounting plate contains aluminum nitride and a spinel. A content ratio of the aluminum nitride in the substrate-mounting plate is 95.0 mass % or more and 99.9 mass % or less. A content ratio of the spinel in the substrate-mounting plate is 0.1 mass % or more and 1.0 mass or less in terms of oxide. The aluminum nitride has a polycrystalline structure. The spinel is positioned at a grain boundary between crystal grains of the aluminum nitride. The spinel has a lattice constant of 8.040 Å or more and 8.110 Å or less.

### BACKGROUND OF THE INVENTION

This application claims priority under 35 U.S.C. Section 119 to International Application PCT/JP2024/013744 filed on Apr. 3, 2024 and Japanese Patent Application No. 2024-210491 filed on Dec. 3, 2024, the contents of which are hereby incorporated by reference into this application.

### BACKGROUND OF THE INVENTION

### 1. Field of the Invention

The present invention relates to a ceramic susceptor.

### 2. Description of the Related Art

In manufacture of a semiconductor device such as an integrated circuit, formation of a desired thin film on a semiconductor substrate, which is supported on a ceramic susceptor including a resistance heating element, is known.

As such ceramic susceptor, for example, a susceptor including a plate including a sintered body containing 90 wt % or more of an aluminum nitride phase, 0.5 wt % to 3.0 wt % of magnesium in terms of MgO, and 0.05 wt % to 0.5 wt % of titanium in terms of TiO₂ has been proposed (see Japanese Patent Application Laid-open No. 2023-047311)

In recent years, formation of a multilayer-structured semiconductor device has advanced, and a plurality of thin films are laminated on a semiconductor substrate in some cases. In this case, it has been desired to reduce the total thickness of a laminated structure by increasing a film formation temperature to reduce the thickness of each of the plurality of thin films.

However, when such film form formation step is performed on the susceptor described in Japanese Patent Application Laid-open No. 2023-047311, warping of a semiconductor substrate due to a residual stress in a thin film may occur. Thus, suppression of the warping of the semiconductor substrate in the film formation step by imparting an electrostatic chuck (ESC) function to the susceptor described in Japanese Patent Application Laid-open No. 2023-047311 has been investigated.

However, when an ESC electrode is arranged on the susceptor described in Japanese Patent Application Laid-open No. 2023-047311 and the film formation step in a high temperature region of 600° C. or more, for example, is performed, the volume resistivity of the plate is reduced and an electric current may leak from the ESC electrode to the plate. When the electric current leaks from the ESC electrode to the plate, the electrostatic chuck function to the semiconductor substrate becomes insufficient, and the semiconductor substrate cannot be supported stably in the film formation step in some cases.

### SUMMARY OF THE INVENTION

A primary object of the present invention is to provide a ceramic susceptor, which can improve the volume resistivity of a substrate-mounting plate in a high temperature region.
[1] According to at least one embodiment of the present invention, there is provided a ceramic susceptor including a substrate-mounting plate. The substrate-mounting plate contains aluminum nitride and a spinel. A content ratio of the aluminum nitride in the substrate-mounting plate is 95.0 mass % or more and 99.9 mass % or less. A content ratio of the spinel in the substrate-mounting plate is 0.1 mass % or more and 1.0 mass % or less in terms of oxide. The aluminum nitride has a polycrystalline structure. The spinel is positioned at a grain boundary between crystal grains of the aluminum nitride. The spinel has a lattice constant of 8.040 Å or more and 8.110 Å or less.
[2] In the ceramic susceptor according to the above-mentioned item [1], the substrate-mounting plate may further contain titanium nitride.
[3] In the ceramic susceptor according to the above-mentioned item [2], a content ratio of the titanium nitride in the substrate-mounting plate may be 0.01 mass % or more and 1.0 mass % or less in terms of oxide.
[4] In the ceramic susceptor according to any one of the above-mentioned items [1] to [3], a volume resistivity of the substrate-mounting plate at 600° C. may be 1.0×10⁹ Ω·cm or more.
[5] In the ceramic susceptor according to any one of the above-mentioned items [1] to [4], a content ratio of x-aluminum oxide in the substrate-mounting plate may be 1.0 mass % or less.
[6] The ceramic susceptor according to any one of the above-mentioned items [1] to [5] may further include an internal electrode embedded in the substrate-mounting plate.
[7] In the ceramic susceptor according to the above-mentioned item [6], the internal electrode may further include a resistance heating element.

### BRIEF DESCRIPTION OF THE DRAWINGS

FIG. 1 is a schematic configuration diagram of a ceramic susceptor according to at least one embodiment of the present invention.

### DESCRIPTION OF THE EMBODIMENTS

Embodiments of the present invention are described below. However, the present invention is not limited to these embodiments. In addition, for clearer illustration, some widths, thicknesses, shapes, and the like of respective portions may be schematically illustrated in the drawings in comparison to the embodiments. However, the widths, the thicknesses, the shapes, and the like are each merely an example, and do not limit the understanding of the present invention.

### A. Outline of Ceramic Susceptor

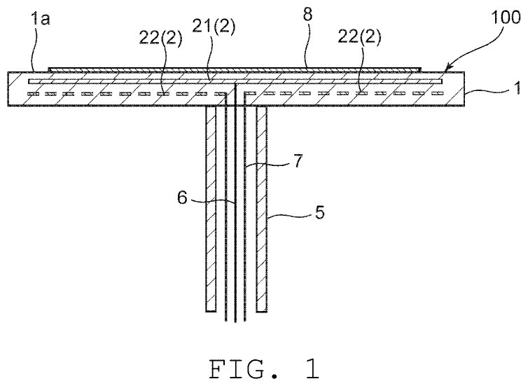

FIG. 1 is a schematic configuration diagram of a ceramic susceptor according to at least one embodiment of the present invention. A ceramic susceptor 100 includes a substrate-mounting plate 1. The substrate-mounting plate 1 may have any appropriate shape. The substrate-mounting plate 1 preferably has a disc shape. The thickness of the substrate-mounting plate 1 is, for example, from 5 mm to 50 mm.

The substrate-mounting plate 1 has a mounting surface 1a on which a semiconductor substrate 8 can be mounted. The mounting surface 1a is typically one surface of the substrate-mounting plate 1 in the thickness direction thereof.

In at least one embodiment of the present invention, the substrate-mounting plate 1 contains aluminum nitride (hereinafter referred to as “AlN”) and a spinel. That is, the substrate-mounting plate 1 contains an AlN crystal phase and a spinel crystal phase. The content ratio of the AlN in the substrate-mounting plate 1 is 95.0 mass % or more and 99.9 mass % or less. The content ratio of the spinel in the substrate-mounting plate 1 is 0.1 mass % or more and 1.0 mass % or less in terms of oxide. The AlN has a polycrystalline structure. The spinel is positioned at a grain boundary between crystal grains of the AlN. The spinel has a lattice constant of 8.040 Å or more and 8.110 Å or less.

The inventors of the present invention have found that a trace amount of a spinel existing on a substrate-mounting plate having an AlN content ratio of 95.0 mass % or more has an influence on the volume resistivity of the substrate-mounting plate in a high temperature region (e.g., 600° C. or more). From the results of intensive investigations on the arrangement and crystalline state of the spinel, the inventors have found that improvement in volume resistivity of the substrate-mounting plate in a high temperature region can be achieved by causing a spinel having a specific lattice constant to exist at a grain boundary between AlN crystal grains.

Specifically, improvement in volume resistivity of the substrate-mounting plate in a high temperature region can be achieved and reduction in volume resistivity of the substrate-mounting plate in a high temperature region can be remarkably suppressed by causing a spinel having a lattice constant of 8.040 Å or more and 8.110 Å or less to exist at a grain boundary between AlN crystal grains.

### A-1. Aluminum Nitride (AlN)

The substrate-mounting plate 1 contains a plurality of AlN crystal grains. Of the plurality of AlN crystal grains, AlN crystal grains adjacent to each other are typically bonded.

The average particle diameter of the plurality of AlN crystal grains is, for example, from 1 μm to 5 μm, preferably from 1 μm to 3 μm.

The content ratio of AlN in the substrate-mounting plate 1 is preferably 97.0 mass % or more, more preferably 98.0 mass& or more. Meanwhile, the content ratio of AlN in the substrate-mounting plate 1 is preferably 99.8 mass % or less, more preferably 99.5 mass % or less, still more preferably 99.0 mass % or less.

When the content ratio of AlN in the substrate-mounting plate falls within such ranges, high thermal conductivity, high toughness, and high dielectric voltage can be developed.

The content ratio of each compositional element in the substrate-mounting plate is measured by, for example, inductively coupled plasma-atomic emission spectroscopy (ICP-AES) in conformity with JIS K 0116. The crystal phase in the substrate-mounting plate is measured by, for example, X-ray diffraction (XRD) in accordance with JIS Z 2201 and JIS K 0114.

### A-2. Spinel

The spinel typically exists at a grain boundary, or is typically formed through a reaction between magnesium oxide and aluminum oxide at a grain boundary between AlN crystal grains.

The crystal system of the spinel is typically a cubic system, more specifically a face-centered cubic system.

The lattice constant of the spinel (i.e., a lattice constant of an a-axis) is preferably 8.050 Å or more, more preferably 8.060 Å or more, still more preferably 8.063 Å or more, even still more preferably 8.064 Å or more, particularly preferably 8.070 Å or more, more particularly preferably 8.075 Å or more.

Meanwhile, the lattice constant of the spinel (i.e., the lattice constant of the a-axis) is preferably 8.100 Å or less, more preferably 8.090 Å or less.

When the lattice constant of the spinel falls within such ranges, further improvement in volume resistivity of the substrate-mounting plate in a high temperature region can be achieved and reduction in volume resistivity of the substrate-mounting plate in a high temperature region can be sufficiently suppressed.

The content ratio of the spinel in the substrate-mounting plate 1 is preferably 0.2 mass % or more, more preferably 0.3 mass % or more in terms of oxide. Meanwhile, the content ratio of the spinel in the substrate-mounting plate 1 is preferably 0.9 mass % or less in terms of oxide. When the content ratio of the spinel in substrate-mounting plate falls within such ranges, the volume resistivity of the substrate-mounting plate in a high temperature region can be stably improved.

### A-3. Titanium Nitride (TiN)

In at least one embodiment of the present invention, the substrate-mounting plate 1 further contains titanium nitride (hereinafter referred to as “TiN”). That is, the substrate-mounting plate 1 contains a TiN crystal phase in addition to the AlN crystal phase and the spinel crystal phase. TiN typically exists at a grain boundary between AlN crystal grains.

The content ratio of TiN in the substrate-mounting plate 1 is, for example, 0.01 mass % or more, preferably 0.3 mass % or more in terms of oxide. Meanwhile, the content ratio of the TiN in the substrate-mounting plate 1 is, for example, 1.0 mass % or less, preferably 0.8 mass % or less in terms of oxide.

The content ratio of the TiN in the substrate-mounting plate preferably falls within such ranges because formation of a conductive path in a grain boundary layer is suppressed, and reduction in volume resistivity of the substrate-mounting plate is suppressed.

### A-4. Other Crystal Phase

The substrate-mounting plate 1 may further contain another crystal phase. The other crystal phase is a crystal phase excluding the AlN crystal phase, the spinel crystal phase, and the TiN crystal phase, and an example thereof is α-aluminum oxide (α-alumina).

The content ratio of the other crystal phase in the substrate-mounting plate 1 is, for example, 1.0 mass % or less. Meanwhile, the lower limit of the content ratio of the other crystal phase in the substrate-mounting plate 1 is typically 0 mass %.

When the content ratio of the other crystal phase in the substrate-mounting plate falls within such range, reduction in volume resistivity of the substrate-mounting plate in a high temperature region can be stably suppressed.

### A-5. Physical Properties of Substrate-Mounting Plate

Such substrate-mounting plate has a relatively high volume resistivity in a high temperature region.

The volume resistivity of the substrate-mounting plate 1 at 600° C. is, for example, 1.0×10⁹ Ω·cm or more, preferably 1.2×10⁹ Ω·cm or more, more preferably 2.0×10⁹ Ω·cm or more, still more preferably 5.0×10⁹ Ω·cm or more, even still more preferably 1.0×10¹⁰ Ω·cm or more, particularly preferably 7.0×10¹⁰ Ω·cm or more, most preferably 8.0×10¹⁰ Ω·cm or more.

Meanwhile, the volume resistivity of the substrate-mounting plate 1 at 600° C. is, for example, 1.0×10¹² Ω·cm or less, or for example, 1.5×10¹¹ Ω·cm or less.

The volume resistivity of the substrate-mounting plate at 600° C. is measured in conformity with JIS C 2141-1992, for example.

In addition, the thermal conductivity of the substrate-mounting plate 1 at 600° C. is, for example, from 20 W/m·K to 50 W/m·K.

The thermal conductivity of the substrate-mounting plate at 600° C. is measured in conformity with, for example, a flash method defined in JIS R 1611:2010.

The apparent porosity of the substrate-mounting plate 1 is, for example, 1.0% or less. The apparent porosity of the substrate-mounting plate is measured in conformity with JIS R 1634, for example.

The relative density of the substrate-mounting plate 1 is, for example, 99.0% or more, preferably 99.5% or more. Meanwhile, the upper limit of the relative density of the substrate-mounting plate 1 is typically 100%. The relative density of the substrate-mounting plate is measured in conformity with JIS R 1634, for example.

### B. Method of producing Substrate-mounting Plate

Next, a method of producing a substrate-mounting plate according to at least one embodiment of the present invention is described.

A method of producing a substrate-mounting plate according to at least one embodiment of the present invention includes a mixing step, a molding step, a calcination step, and a firing step in the stated order.

### B-1. Mixing Step

In the mixing step, at least an AlN raw material and a magnesium oxide raw material (hereinafter referred to as “MgO raw material”) are mixed, or an AlN raw material and a spinel raw material are mixed to prepare a mixture.

The AlN raw material contains AlN as a main component. The AlN raw material may contain oxygen and carbon in addition to AlN.

The content of oxygen in the AlN raw material is, for example, from 0.7 mass % to 0.9 mass %. The content of carbon in the AlN raw material is, for example, from 200 ppm to 400 ppm.

The AlN raw material is typically in a powder form. The average particle diameter D50 of the AlN raw material is, for example, 1 μm.

The MgO raw material contains MgO as a main component. The MgO raw material is typically in a powder form. The average particle diameter D50 of the MgO raw material is, for example, 0.5 μm.

The addition amount of the MgO raw material is, for example, 0.1 part by mass or more, preferably 0.2 part by mass or more, still more preferably 0.4 part by mass or more with respect to 100 parts by mass of the AlN raw material. Meanwhile, the addition amount of the MgO raw material is, for example, 1.1 parts by mass or less, preferably 1.0 part by mass or less, more preferably 0.9 part by mass or less with respect to 100 parts by mass of the AlN raw material.

In the mixing step, a titanium oxide raw material (hereinafter referred to as “TiO₂ raw material”) is further mixed into the AlN raw material and the MgO raw material (or the spinel raw material) as required.

The TiO₂ raw material contains TiO₂ as a main component. The TiO₂ raw material is typically in a powder form. The average particle diameter D50 of the TiO₂ raw material is, for example, 0.3 μm.

The addition amount of the TiO₂ raw material is, for example, 0.1 part by mass or more, preferably 0.3 part by mass or more with respect to 100 parts by mass of the AlN raw material. Meanwhile, the addition amount of the TiO₂ raw material is, for example, 1.0 part by mass or less with respect to 100 parts by mass of the AlN raw material.

In at least one embodiment of the present invention, in the mixing step, a binder is added to the AlN raw material and the MgO raw material.

Examples of the binder include a polyvinyl acetal-based resin, a cellulose ether-based resin, a (meth)acrylic resin, and a paraffin wax. The (meth)acrylic resin includes an acrylic resin and/or a methacrylic resin. The binders may be used alone or in combination thereof.

Of such binders, a (meth)acrylic resin is preferred.

In the mixing step, any appropriate mixing apparatus may be used. Examples of the mixing apparatus include a ball mill, a bead mill, a vibration mill, a rocking mixer, a blender, and a homogenizer.

In addition, a mixing method may involve dry mixing or wet mixing. In at least one embodiment of the present invention, wet mixing is performed in the mixing step. Any appropriate solvent is used in the wet mixing. Examples of the solvent include: alcohols, such as isopropyl alcohol and ethanol; and aromatic hydrocarbons, such as toluene and xylene.

Environment conditions in the mixing step are not particularly limited. The mixing step is typically performed under normal temperature (23° C.) and normal pressure (0.1 MPa).

A mixing time is freely and appropriately set. The mixing time is, for example, from 1 hour to 24 hours.

Thus, a mixture containing at least the AlN raw material and the MgO raw material (or the spinel raw material) is prepared. When the mixing step involves dry mixing, the mixture is in a powder form, and when the mixing step involves wet mixing, the mixture is in a slurry form.

### B-2. Granulation Step

In at least one embodiment of the present invention, the method of producing a substrate-mounting plate includes a granulation step after the mixing step and before the molding step.

In the granulation step, the mixture obtained in the mixing step is granulated by any appropriate granulation method. Examples of the granulation method include spray granulation and tumbling granulation, and spray granulation is preferred.

Thus, a granulated product (hereinafter referred to as “raw material granules”) of the mixture is prepared.

### B-3. Molding Step

Next, in the molding step, the mixture (preferably, raw material granules) is molded into a desired shape by any appropriate molding method.

Examples of the molding method include press molding, sheet molding, and cold isostatic press (CIP) molding, and press molding is preferred. The pressure in the press molding is, for example, from 10 kgf/cm² to 500 kgf/cm².

Thus, a molded body having a desired shape is prepared.

### B-4. Firing Step

Next, in the firing step, the molded body is typically fired under a vacuum or a non-oxidizing atmosphere. More specifically, the temperature is increased from normal temperature (23° C.) to a predetermined firing temperature, and the firing temperature is then maintained for a predetermined firing time. A debindering step may be provided before the firing step as required.

The firing temperature is, for example, from 1,600° C. to 1,900° C., preferably from 1,650° C. to 1, 850° C.

The firing time is, for example, from 0.5 hour to 100 hours.

The ambient pressure in the firing step is, for example, from 100 kPa to 900 kPa.

Examples of a firing method include hot pressing and hot isostatic pressing (HIP), and hot pressing is preferred.

In the hot pressing, the molded body is typically placed in a hot press die (e.g., a carbon jig), heated to the firing temperature as described above, and pressed under a predetermined pressure. The pressure in the hot pressing is, for example, from 5 MPa to 50 MPa.

After that, the temperature is decreased from the firing temperature to normal temperature (23° C.). A temperature decrease rate is freely and appropriately adjusted in accordance with the addition amount of the MgO raw material described above. The temperature decrease rate is, for example, 250° C./hr or less, preferably 150° C./hr or less, more preferably 120° C./hr or less. When the temperature decrease rate is equal to or less than such upper limits, the lattice constant of the spinel formed in the firing step can be stably adjusted within the above-mentioned ranges.

Meanwhile, the temperature decrease rate is, for example, 50° C./hr or more, preferably 80° C./hr or more.

In such firing step, the raw materials described above are sintered and undergo a reaction to form a composite sintered body containing the AlN and the spinel.

Thus, a substrate-mounting plate having a desired shape is prepared. The substrate-mounting plate is typically formed of the composite sintered body.

### C. Details of Ceramic Susceptor

The ceramic susceptor 100 may be formed of the substrate-mounting plate 1 alone, or may further include another member in addition to the substrate-mounting plate 1.

As illustrated in FIG. 1, the ceramic susceptor further includes an internal electrode 2 in addition to the substrate-mounting plate 1 described above.

The internal electrode 2 is embedded in the substrate-mounting plate 1. For embedding of the internal electrode 2 in the substrate-mounting plate 1, for example, in the molding step described above, the mixture is molded under a state in which the internal electrode 2 is embedded in a desired position of the mixture. After that, the calcination step and the firing step are performed.

The internal electrode 2 is positioned at a predetermined distance from the mounting surface 1a in the thickness direction of the substrate-mounting plate 1.

In the thickness direction of the substrate-mounting plate 1, the distance between the mounting surface 1a and the internal electrode 2 is, for example, from 0.1 mm to 3.0 mm.

Examples of the internal electrode 2 include an ESC electrode, a RF electrode, and a resistance heating element.

In the illustrated example, the ceramic susceptor 100 includes an ESC electrode 21 as the internal electrode 2.

When the internal electrode 2 includes the ESC electrode 21, at the time of the application of a voltage to the ESC electrode 21 under a state in which the semiconductor substrate 8 is mounted on the mounting surface 1a, the ESC electrode 21 is charged with one of positive charge and negative charge, and the other one of positive charge and negative charge inherent in the semiconductor substrate 8 moves to the mounting surface 1a side of the semiconductor substrate 8. Consequently, a Coulomb force is generated between the semiconductor substrate 8 and the ESC electrode 21, and hence the semiconductor substrate 8 is chucked to the substrate-mounting plate 1.

The ceramic susceptor 100 may include a plurality of ESC electrodes 21 (not shown). The plurality of ESC electrodes 21 are positioned apart from each other in the plane direction perpendicular to the thickness direction of the substrate-mounting plate 1 under a state in which the electrodes are embedded in the substrate-mounting plate 1.

When the ceramic susceptor 100 includes the plurality of ESC electrodes 21, at the time of the application of a voltage to the plurality of ESC electrodes 21, part of the plurality of ESC electrodes 21 is charged positive, and the remainder of the plurality of ESC electrodes 21 is charged negative. Thus, the semiconductor substrate 8 may be chucked to the substrate-mounting plate 1 in a multizone.

In at least one embodiment of the present invention, the internal electrode 2 functions as a radio-frequency electrode (that is, a RF electrode) for plasma treatment. In the illustrated example, the ESC electrode 21 also functions as a RF electrode. That is, the ESC electrode 21 preferably functions as a RF/ESC electrode. Examples of the plasma treatment include film formation treatment and etching treatment.

When the semiconductor substrate 8 on the mounting surface 1a is subjected to such plasma treatment, an upper electrode is arranged on the side of the semiconductor substrate 8 opposite to the RF electrode. When radio-frequency power is supplied to the RF electrode in this state, a processing gas can be excited to generate plasma in a space between the substrate-mounting plate 1 and the upper electrode. The semiconductor substrate 8 is subjected to plasma treatment with the plasma.

The ESC electrode 21 may have any appropriate shape. The ESC electrode 21 typically has a plate shape. In at least one embodiment of the present invention, the ESC electrode 21 has a shape similar to the outer shape of the substrate-mounting plate 1 as viewed in the thickness direction of the substrate-mounting plate 1. In the illustrated example, the center of the ESC electrode 21 and the center of the substrate-mounting plate 1 substantially coincide with each other as viewed in the thickness direction of the substrate-mounting plate 1.

The thickness of the ESC electrode 21 is, for example, from 0.1 mm to 1.0 mm.

The ESC electrode 21 is formed of any appropriate conductive material. A typical example of the conductive material is a metal having a relatively high melting point. Examples of such metal include tantalum (Ta), tungsten (W), molybdenum (Mo), platinum (Pt), rhenium (Re), hafnium (Hf), and alloys thereof. Such metals may be used alone or in combination thereof.

In the illustrated example, a first power feeding rod 6 is electrically connected to the ESC electrode 21. The above-mentioned voltage (or radio-frequency power) may be applied to the ESC electrode 21 through the first power feeding rod 6. The first power feeding rod 6 is typically formed of the same metal as that of the ESC electrode 21.

In at least one embodiment of the present invention, the ceramic susceptor 100 further includes a resistance heating element 22 as the internal electrode 2.

In the illustrated example, the resistance heating element 22 is positioned on the side of the ESC electrode 21 opposite to the mounting surface 1a of the substrate-mounting plate 1.

For the embedding of the resistance heating element 22 in the substrate-mounting plate 1, for example, in the molding step described above, the mixture is molded under a state in which the resistance heating element 22 is embedded in a desired position of the mixture. After that, the firing step is performed.

The resistance heating element 22 is configured to generate heat when a voltage is applied thereto.

The resistance heating element 22 has any appropriate shape. Examples of the shape of the resistance heating element 22 include a coil shape, a zigzag shape, and a mesh shape. In the illustrated example, the resistance heating element 22 has a coil shape. The resistance heating element 22 may be formed by printing.

The resistance heating element 22 is formed of any appropriate conductive material. A typical example of the conductive material is a metal having a relatively high melting point. Examples of such conductive material include tantalum (Ta), tungsten (W), molybdenum (Mo), tungsten carbide (WC), titanium nitride (TiN), platinum (Pt), rhenium (Re), hafnium (Hf), and alloys thereof. Such conductive materials may be used alone or in combination thereof.

Of the conductive materials, W, Mo, a W—Mo alloy, WC, and a WC—TiN alloy are preferred.

In the illustrated example, a second power feeding rod 7 is electrically connected to the resistance heating element 22. The voltage described above may be applied to the resistance heating element 22 through the second power feeding rod 7. The second power feeding rod 7 is typically formed of the same conductive material as that of the resistance heating element 22.

The ceramic susceptor 100 may further include a ceramic shaft 5. The ceramic shaft 5 is capable of supporting the substrate-mounting plate 1. The ceramic shaft 5 is connected to the surface of the substrate-mounting plate 1 on the side opposite to the mounting surface 1a.

The ceramic shaft 5 has any appropriate shape. In at least one embodiment of the present invention, the ceramic shaft 5 has a cylindrical shape extending in the thickness direction of the substrate-mounting plate 1. In the illustrated example, the shaft line of the ceramic shaft 5 and the center of the substrate-mounting plate 1 substantially coincide with each other as viewed in the thickness direction of the substrate-mounting plate 1. In addition, the first power feeding rod 6 extends through an internal space of the ceramic shaft 5 and is connected to the internal electrode 2. In addition, the second power feeding rod 7 extends through the internal space of the ceramic shaft 5 and is connected to the resistance heating element 22.

The ceramic shaft 5 is formed of any appropriate ceramic material. The ceramic shaft 5 is formed of, for example, aluminum nitride, and is preferably formed of the same material as that of the substrate-mounting plate 1.

Such ceramic susceptor may be applied to any appropriate industrial product. Examples of the application of the ceramic susceptor include a susceptor, a ceramic heater, and an electrostatic chuck.

With such ceramic susceptor 100, the lattice constant of the spinel in the substrate-mounting plate 1 falls within the above-mentioned ranges, and hence improvement in volume resistivity of the substrate-mounting plate in a high temperature region of 600° C. or more, for example, can be achieved. Thus, in plasma treatment such as film formation treatment, the leakage of an electric current from the internal electrode 2 can be remarkably suppressed, and the electrostatic chuck function to the semiconductor substrate 8 can be sufficiently developed.

### Examples

The present invention is specifically described below by way of Examples and Comparative Examples. However, the present invention is not limited by these Examples. Measurement methods for characteristics are as described below.

### (1) Measurement of Volume Resistivity of Substrate-Mounting Plate

The volume resistivity of the substrate-mounting plate produced in each of Examples and Comparative Examples at 600° C. was measured under a vacuum atmosphere in conformity with JIS C 2141-1992. More specifically, a test piece having a disc shape was prepared from the substrate-mounting plate. The diameter of the test piece was 50 mm, and the thickness of the test piece was 1 mm. Next, a main electrode and a guard electrode were arranged on an upper surface of the test piece, and an applicator was arranged on a lower surface of the test piece. The main electrode, the guard electrode, and the applicator were each formed of silver (Ag). The diameter of the main electrode was 20 mm. The inner diameter of the guard electrode was 30 mm, and the outer diameter of the guard electrode was 40 mm. The diameter of the applicator was 45 mm.

Next, a voltage of 500 V/mm was applied to the test piece. The current value 1 minute after the voltage application was read, and the volume resistivity was calculated from the current value. The test piece was evaluated by the following criteria. Table 1 shows the results.

o: The volume resistivity of the substrate-mounting plate at 600° C. was 1×10⁹ Ω·cm or more.
x: The volume resistivity of the substrate-mounting plate at 600° C. was less than 1×10⁹ Ω·cm.

### (2) Identification of Crystal Phases and Calculation of Content Ratio of Each Crystal Phase in Substrate-Mounting Plate

The substrate-mounting plate produced in each of Examples and Comparative Examples was pulverized in a mortar, and then silicon (Si) powder serving as an internal standard sample was added thereto and mixed. The resultant mixed powder was analyzed with an X-ray diffraction (XRD) apparatus, to thereby identify the crystal phases in the substrate-mounting plate. Table 1 shows the results.

The measurement conditions were as follows: CuKa; 40 kV; 40 mA; and 2θ of from 20° to 80°. A sealed tube-type X-ray diffractometer (D8 ADVANCE, manufactured by Bruker AXS) was used. The step size of the measurement was 0.02°.

In addition, the content ratio of each crystal phase in the substrate-mounting plate was calculated by XRD. Table 1 shows the results.

### (3) Calculation of Lattice Constant of Spinel in Substrate-Mounting Plate

The lattice constant of the spinel in the substrate-mounting plate produced in each of Examples and Comparative Examples was calculated by a whole powder pattern decomposition (WPPD) method employing software (TOPAS, manufactured by Bruker AXS). Table 1 shows the results.

### Example 1

AlN raw material powder (average particle diameter D50: 1.2 μm, oxygen content: 0.8 mass %), MgO raw material powder (average particle diameter D50: 0.5 μm), and TiO₂ raw material powder (average particle diameter D50: 0.3 μm) were loaded into a ball mill in the formulation shown in Table 1. Further, an acrylic resin (binder) and isopropyl alcohol (IPA) were loaded into the ball mill, and the resultant was subjected to wet mixing for 2 hours.

Next, the resultant slurry was subjected to dry granulation with a spray granulation apparatus to provide raw material granules. The diameter of the raw material granules was 80 μm.

Next, the raw material granules were subjected to uniaxial press molding to provide a molded body having a disc shape. The pressure in the uniaxial pressing was 100 kgf/cm².

Next, the molded body was subjected to a debindering step and was then fired by a hot pressing method. More specifically, the molded body was fired at 1, 800° C. for 2 hours under a nitrogen atmosphere, and was then cooled at a temperature decrease rate of 100° C./hr. In this way, a substrate-mounting plate was obtained.

### Examples 2 to 6, and Comparative Examples 1 and 2

Substrate-mounting plates were each obtained in the same manner as in Example 1 except that: the addition amounts of the AlN raw material powder, the MgO raw material powder, and the TiO₂ raw material powder were changed to the formulation shown in Table 1; and the temperature decrease rate was changed as shown in Table 1.

TABLE 1

| | | | Example | Example | Example | Example | Example | Example |
|---|---|---|---|---|---|---|---|---|
| No. | | | 1 | 2 | 3 | 4 | 5 | 6 |
| Formulation | AlN raw material | | 99.3 | 99.7 | 98.9 | 98.5 | 98.7 | 99.0 |
| [part(s) by | MgO raw material | | 0.1 | 0.3 | 0.6 | 1.0 | 0.9 | 0.7 |
| mass] | TiO₂ raw material | | 0.6 | 0 | 0.5 | 0.5 | 0.4 | 0.3 |
| Temperature decrease rate | | | 100 | 100 | 100 | 100 | 80 | 50 |
| [° C./hr] | | | | | | | | |
| Substrate- | Crystal | AlN | 99.3 | 99.7 | 98.9 | 98.5 | 98.7 | 99.0 |
| mounting | phase | Spinel | 0.1 | 0.3 | 0.6 | 1.0 | 0.9 | 0.7 |
| plate | [mass %] | TiN | 0.6 | 0 | 0.5 | 0.5 | 0.4 | 0.3 |

| | | | | | | |
|---|---|---|---|---|---|---|
| Spinel lattice | 8.062 | 8.063 | 8.081 | 8.100 | 8.089 | 8.073 |
| constant [Å] | | | | | | |
| Volume | 1.3 × 10⁹ | 2.5 × 10⁹ | 9.0 × 10¹⁰ | 1.3 × 10⁹ | 4.3 × 10¹⁰ | 1.8 × 10¹⁰ |
| resistivity at | | | | | | |
| 600° C. [Ω · cm] | | | | | | |
| Evaluation | ∘ | ∘ | ∘ | ∘ | ∘ | ∘ |

| | | Comparative | Comparative |
|---|---|---|---|
| No. | | Example 1 | Example 2 |
| Formulation | AlN raw material | 98.9 | 98.3 |
| [part(s) by | MgO raw material | 0.6 | 1.2 |
| mass] | TiO₂ raw material | 0.5 | 0.5 |

| Temperature decrease rate | | | | 200 | 100 |
|---|---|---|---|---|---|
| [° C./hr] | | | | | |
| | Substrate- | Crystal | AlN | 98.9 | 98.3 |
| | mounting | phase | Spinel | 0.6 | 1.2 |
| | plate | [mass %] | TiN | 0.5 | 0.5 |

| | | |
|---|---|---|
| Spinel lattice | 8.028 | 8.125 |
| constant [Å] | | |
| Volume | 2.2 × 10⁷ | 4.5 × 10⁸ |
| resistivity at | | |
| 600° C. [Ω · cm] | | |
| Evaluation | x | x |

### [Evaluation]

As is apparent from Table 1, when the spinel having a lattice constant of from 8.060 Å to 8.100 Å is caused to exist at a grain boundary in the substrate-mounting plate having a content ratio of aluminum nitride (AlN) of 95.0% or more, improvement in volume resistivity of the substrate-mounting plate at 600° C. can be achieved.

The ceramic susceptor according to at least one embodiment of the present invention can be used in various industrial products, and in particular, can be suitably used as a ceramic susceptor included in a manufacturing apparatus for a semiconductor device.

According to at least one embodiment of the present invention, the ceramic susceptor, which has improved the volume resistivity of a substrate-mounting plate in a high temperature region, can be achieved.

What is claimed is:

1. A ceramic susceptor, comprising a substrate-mounting plate containing aluminum nitride and a spinel,
wherein a content ratio of the aluminum nitride in the substrate-mounting plate is 95.0 mass % or more and 99.9 mass % or less,
wherein a content ratio of the spinel in the substrate-mounting plate is 0.1 mass % or more and 1.0 mass % or less in terms of oxide,
wherein the aluminum nitride has a polycrystalline structure,
wherein the spinel is positioned at a grain boundary between crystal grains of the aluminum nitride, and
wherein the spinel has a lattice constant of 8.040 Å or more and 8.110 Å or less.

2. The ceramic susceptor according to claim 1, wherein the substrate-mounting plate further contains titanium nitride.

3. The ceramic susceptor according to claim 2, wherein a content ratio of the titanium nitride in the substrate-mounting plate is 0.01 mass % or more and 1.0 mass % or less in terms of oxide.

4. The ceramic susceptor according to claim 1, wherein a volume resistivity of the substrate-mounting plate at 600° C. is 1.0×10⁹ Ω·cm or more.

5. The ceramic susceptor according to claim 1, wherein a content ratio of α-aluminum oxide in the substrate-mounting plate is 1.0 mass % or less.

6. The ceramic susceptor according to claim 1, further comprising an internal electrode embedded in the substrate-mounting plate.

7. The ceramic susceptor according to claim 6, wherein the internal electrode includes a resistance heating element.

8. A ceramic susceptor, comprising
a substrate-mounting plate containing aluminum nitride and a spinel, and
an internal electrode embedded in the substrate-mounting plate,
wherein a content ratio of the aluminum nitride in the substrate-mounting plate is 95.0 mass % or more and 99.9 mass % or less,
wherein a content ratio of the spinel in the substrate-mounting plate is 0.1 mass % or more and 1.0 mass % or less in terms of oxide,
wherein the aluminum nitride has a polycrystalline structure,
wherein the spinel is positioned at a grain boundary between crystal grains of the aluminum nitride,
wherein the spinel has a lattice constant of 8.040 Å or more and 8.110 Å or less,
wherein a content ratio of α-aluminum oxide in the substrate-mounting plate is 1.0 mass % or less,
wherein a volume resistivity of the substrate-mounting plate at 600° C. is 1.0×10⁹ Ω·cm or more, and
wherein the internal electrode includes a resistance heating element.
